(19) United States
(12) Patent Application Publication
(10) Pub. No.: US 2015/0162373 A1
(43) Pub. Date: Jun. 11, 2015

(54) IMAGE SENSOR, MANUFACTURING METHOD OF THE SAME, AND IMAGE PROCESSING SYSTEM INCLUDING THE IMAGE SENSOR

(71) Applicants: Tae Chan KIM, Yongin-si (KR); Seoung Hyun KIM, Hwaseong-si (KR)

(72) Inventors: Tae Chan KIM, Yongin-si (KR); Seoung Hyun KIM, Hwaseong-si (KR)

(21) Appl. No.: 14/566,864

(22) Filed: Dec. 11, 2014

(30) Foreign Application Priority Data
Dec. 11, 2013 (KR) 10-2013-0154177

(51) Int. Cl. H01L 27/146; H01L 31/0232

(52) U.S. Cl. CPC H01L 27/14645; H01L 27/14625; H01L 27/14612; H01L 31/02322

(57) ABSTRACT

An image sensor is provided. The image sensor includes a photoelectric converter formed on a first layer and configured to generate light charges by receiving light, a read circuit formed on a second layer below the first layer and configured to accumulate the generated light charges and produce a video signal according to an amount of the accumulated light charges, and a light charge transfer layer formed on a third layer between the first and second layers and configured to transfer the generated light charges to the read circuit. The read circuit includes a single transistor, and the light charges are accumulated in a body of the single transistor.

### CROSS-REFERENCE TO RELATED APPLICATIONS

This application claims priority from Korean Patent Application No. 10-2013-0154177, filed on Dec. 11, 2013, in the Korean Intellectual Property Office, the disclosure of which is incorporated by reference herein in its entirety.

### BACKGROUND

Devices, methods, and articles of manufacture consistent with the present disclosure relate to an image sensor, a method of manufacturing the image sensor, and an image processing system including the image sensor.

Complementary metal-oxide semiconductor (CMOS) image sensors are sensing devices using a CMOS. CMOS image sensors are cheap to manufacture, have a small size, and thus consume low power compared to charge-coupled device (CCD) image sensors including high-voltage analog circuits. Also, as the performance of CMOS image sensors have improved from an initial development stage, CMOS image sensors have been generally installed in household appliances and portable devices such as smartphones, digital cameras, etc.

As CMOS image sensors have been used for various purposes, pixel arrays of the CMOS image sensors and driving circuits thereof are tending to be smaller and smaller. Also, as high-resolution images have become more common regardless of the trend of small-sized pixels of CMOS image sensors, research has been conducted on a method of increasing the resolution of images while reducing the sizes of pixel arrays and driving circuits thereof.

When analog pixels are used in a CMOS image sensor, a full well capacity is limited and research has been thus conducted on development of a binary sensor using digital pixels. However, the binary sensor is vulnerable to sensitivity.

### SUMMARY

It is an aspect provide an image sensor having an improved resolution or sensitivity, a method of manufacturing the image sensor, and an image processing system including the image sensor.

According to an aspect of an exemplary embodiment, there is provided an image sensor which includes a photoelectric converter formed on a first layer and configured to generate light charges by receiving light; a read circuit formed on a second layer below the first layer, and configured to accumulate the generated light charges and produce a video signal according to an amount of the accumulated light charges; and a light charge transfer layer formed on a third layer between the first layer and the second layer, and configured to transfer the generated light charges to the read circuit, wherein the read circuit includes a single transistor, and the light charges are accumulated in a body of the single transistor.

A threshold voltage of the single transistor may vary according to the amount of the light charges accumulated in the body.

The light charges may be transferred from the photoelectric converter to a source or a drain of the single transistor or a region adjacent to the source or the drain, and then accumulated in the body of the single transistor.

The photoelectric converter may include at least one quantum dot.

The at least one quantum dot may include red quantum dots, green quantum dots, and blue quantum dots.

The at least one quantum dot may be excited by visible light to emit light.

The at least one quantum dot may include a central body containing cadmium selenide (CdSe); and a skin containing zinc sulfide (ZnS).

The at least one quantum dot may comprise a plurality of quantum dots, and each quantum dot may emit visible light having a different color that the other quantum dots according to a size of particles thereof.

The at least one quantum dot may have a size of about 1 nm to about 100 nm.

The photoelectric converter may include at least one photodiode.

The image sensor may further include a color filter or an infrared pass filter formed on the first layer to be in contact with the first layer.

The image sensor may include a first silicon substrate including the first layer; and a second silicon substrate including the second layer, and the second silicon substrate may be combined with a bottom of the first silicon substrate.

According to another aspect of an exemplary embodiment, there is provided a method of manufacturing an image sensor, the method including preparing a first wafer including a read circuit of a pixel; forming a first contact layer including at least one first through-electrode on the first wafer; preparing a second wafer including a second contact layer including at least one second through-electrode, and a photoelectric converter; and arranging the at least one first through-electrode and the at least one second through-electrode, and combining the first wafer and the second wafer to connect the at least one first through-electrode and the at least one second through-electrode, wherein the pixel is a binary pixel including a single transistor capable of accumulating light charges in a body thereof.

The method may further include removing at least a portion of a substrate disposed on the photoelectric converter of the second wafer after the first wafer and the second wafer are combined.

The method may further include forming a color filter or an infrared pass filter on the photoelectric converter after the at least a portion of the substrate is removed.

According to another aspect of an exemplary embodiment, there is provided a method of manufacturing an image sensor, the method including preparing a first wafer including a read circuit of a pixel; forming a light charge transfer layer on the first wafer; depositing amorphous silicon on the light charge transfer layer; and forming a photoelectric converter by doping the amorphous silicon, wherein the pixel is a binary pixel including a single transistor capable of accumulating light charges in a body thereof.

The doping the amorphous silicon may include doping n-type impurities or doping p-type impurities into the amorphous silicon.

The forming of the photoelectric converter by doping the amorphous silicon may include forming quantum dots by doping a nano-crystal into the amorphous silicon.

According to another aspect of an exemplary embodiment, there is provided an image processing system which includes an image sensor; and an image processor configured to process an output signal of the image sensor. The image sensor includes a quantum dot layer configured to generate light charges by receiving light; a light charge transfer layer formed below the quantum dot layer and configured to transfer the light charges downward; and a read circuit layer formed below the light charge transfer layer, including at least one binary pixel each including a single transistor, and configured to accumulate the light charges in a body of the single transistor and generate the output signal according to an amount of the light charges accumulated in the body.

### BRIEF DESCRIPTION OF THE DRAWINGS

Exemplary embodiments will be more clearly understood from the following detailed description taken in conjunction with the accompanying drawings in which:

FIG. 1 is a block diagram of an image processing system according to an exemplary embodiment;

FIG. 2 is a block diagram of an image sensor of FIG. 1 according to an exemplary embodiment;

FIG. 3 is a block diagram of an image sensor of FIG. 1 according to another exemplary embodiment;

FIG. 4A is a circuit diagram of a sub-pixel of FIGS. 2 and 3 according to an exemplary embodiment;

FIG. 4B is a circuit diagram of a sub-pixel of FIGS. 2 and 3 according to another exemplary embodiment;

FIG. 5A is a diagram illustrating an image sensor according to an exemplary embodiment;

FIG. 5B is a diagram illustrating an image sensor according to another exemplary embodiment;

FIG. 6 is a diagram illustrating an image sensor according to another exemplary embodiment;

FIG. 7 is a diagram illustrating an operation of the image sensor of FIG. 6 according to an exemplary embodiment;

FIG. 8 is a flowchart of a method of manufacturing an image sensor according to an exemplary embodiment;

FIG. 9 is a flowchart of a method of manufacturing the image sensor of FIG. 6 according to an exemplary embodiment;

FIGS. 10 to 14 are cross-sectional views sequentially illustrating a method of manufacturing the image sensor of FIG. 6 according to an exemplary embodiment;

FIG. 15 is a block diagram of an image sensing system including an image sensor illustrated in FIG. 1 according to some exemplary embodiments; and

FIG. 16 is a block diagram of an image sensing system including an image sensor illustrated in FIG. 1 according to other exemplary embodiments.

### DETAILED DESCRIPTION OF EXEMPLARY EMBODIMENTS

Exemplary embodiments now will be described more fully hereinafter with reference to the accompanying drawings, in which exemplary embodiments are shown. Exemplary embodiments may, however, be implemented in many different forms and should not be construed as limited to the exemplary embodiments set forth herein. Rather, these exemplary embodiments are provided so that this disclosure will be thorough and complete, and will fully convey the scope to those skilled in the art. In the drawings, the size and relative sizes of layers and regions may be exaggerated for clarity. Like numbers refer to like elements throughout.

It will be understood that when an element is referred to as being “connected” or “coupled” to another element, the element can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms “first,” “second,” etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing exemplary embodiments only and is not intended to be limiting. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

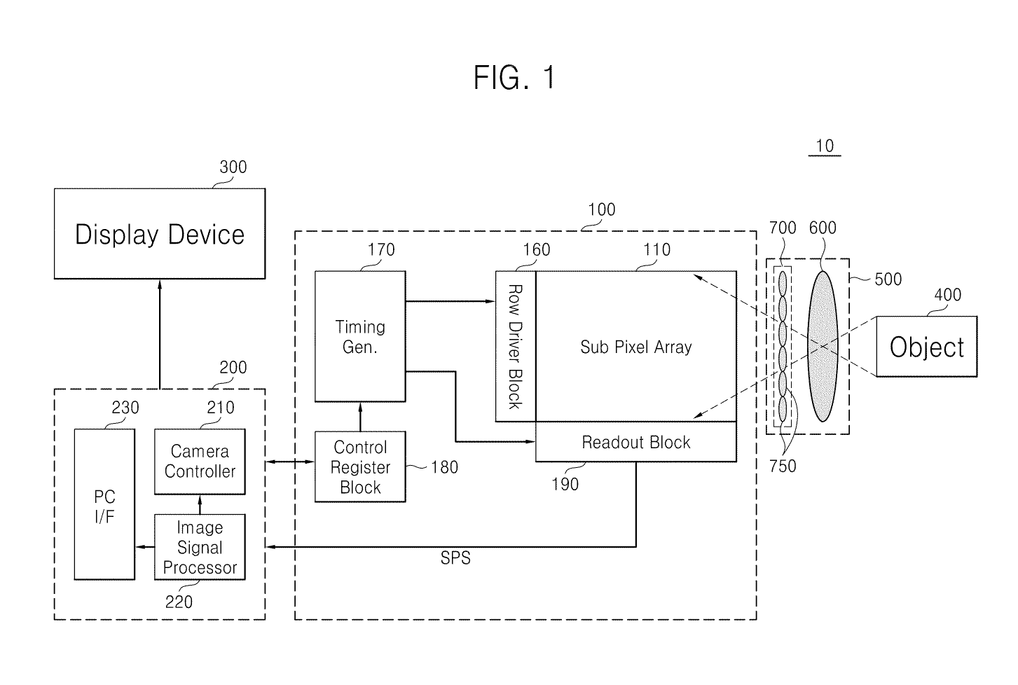

FIG. 1 is a block diagram of an image processing system according to an exemplary embodiment.

Referring to FIG. 1, an image processing system 10 may include an image sensor 100, an image processor 200, a display device 300, and a lens 500.

The image sensor 100 may include a sub-pixel array 110, a row driver block 160, a control register block 180, and a readout block 190.

The image sensor 100 may be controlled by the image processor 200 to sense an object 400 captured through the lens 500. The image processor 200 may output an image sensed by and output from the image sensor 100 to the display device 300. In this case, the display device 300 may be any of various devices capable of outputting an image. For example, the display device 300 may be embodied as a computer, a mobile phone, an electronic device with a camera, or the like.

The image processor 200 may include a camera controller 210, an image signal processor 220, and a personal computer interface (PC I/F) 230. The camera controller 210 controls the control register block 180. In this case, the camera controller 210 may control the image sensor 100 (particularly, the control register block 180) using an Inter-Integrated Circuit (I2C) but the scope of the present disclosure is not restricted thereto.

The image signal processor 220 may receive a sub-pixel signal SPS which is an output signal of the readout block 190, and generate image data by processing the sub-pixel signal SPS in units of sub-pixels or pixels so that the image data may be viewed by a human. The image signal processor 220 outputs the image data to the display device 300 via the PC I/F 230.

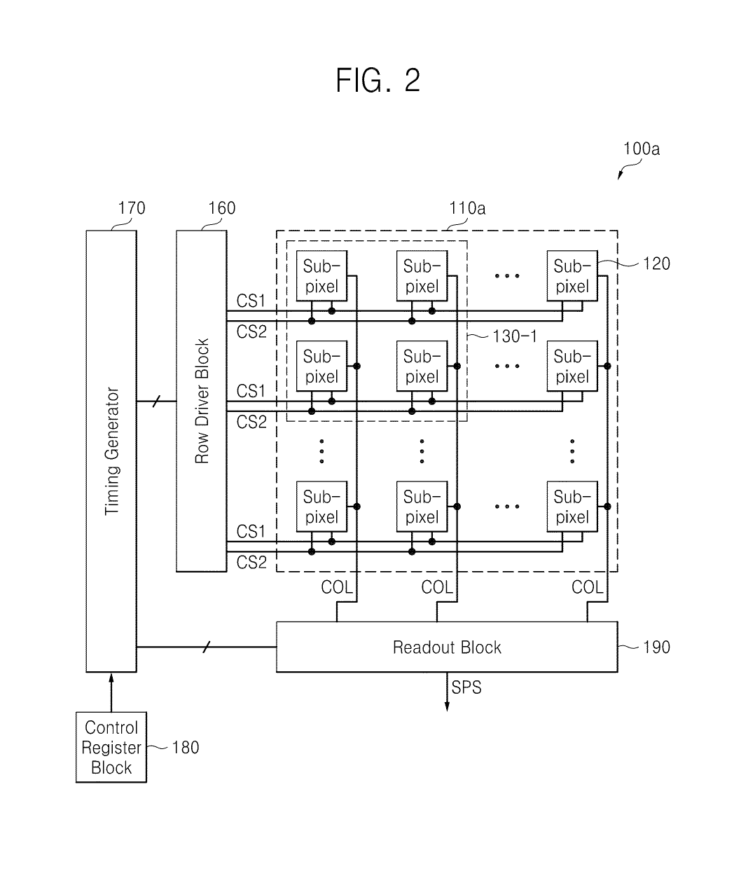

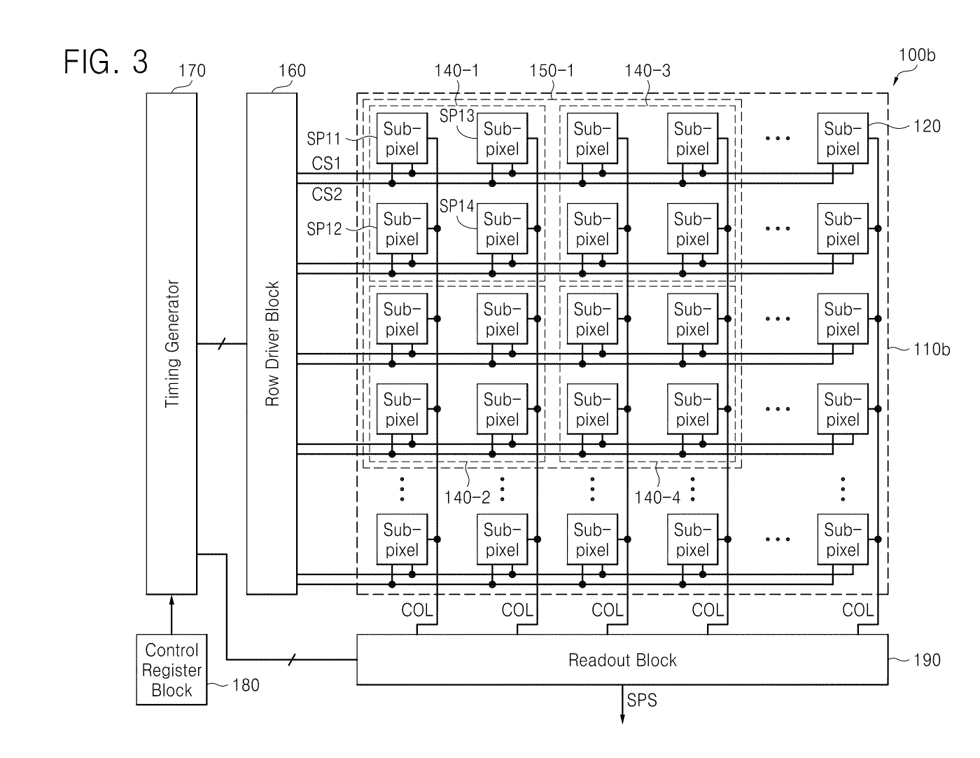

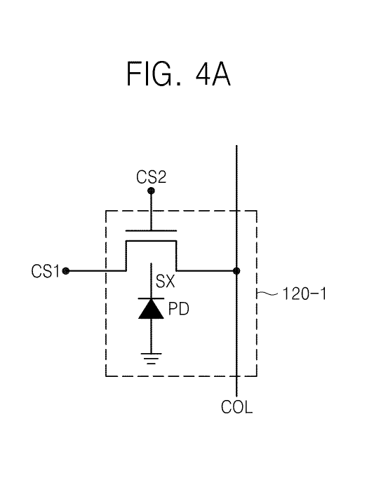

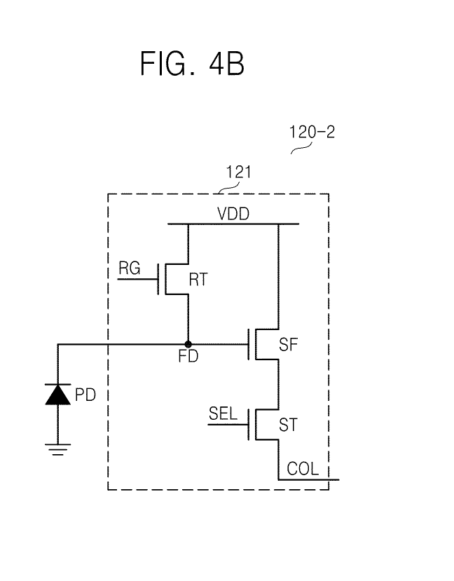

The sub-pixel array 110 may include a plurality of sub-pixels 120 (see FIGS. 2 and 3). Each of the sub-pixels 120 may sense incident light received via the lens 500 and output signals to form the sub-pixel signal SPS, under control of the row driver block 160. The sub-pixel signal SPS may be a digital signal having at least two levels. The sub-pixels 120 will be described in detail with reference to FIGS. 4A and 4B below.

A timing generator 170 may output a control signal and/or a clock signal to the row driver block 160 and the readout block 190 so as to control operations and/or timings of the row driver block 160 and the readout block 190.

In some exemplary embodiments, the control register block 180 is operated under control of the camera controller 210, and stores various commands and/or instructions for operating the image sensor 100.

Turning to FIGS. 2 and 3, the row driver block 160 drives the sub-pixel array 110 in units of rows. For example, the row driver block 160 may supply a first control signal CS1 and a second control signal CS2 (see FIGS. 2 and 3) to sub-pixels that constitute the sub-pixel array 110. That is, the first control signal CS1 and the second control signal CS2 may be supplied to each of the rows of the sub-pixel array 110 by decoding the control signal output from the timing generator 170.

The sub-pixel array 110 outputs a signal that forms the sub-pixel signal SPS to the readout block 190 from a row selected according to the first control signal CS 1 and the second control signal CS2 supplied from the row driver block 160.

The readout block 190 temporarily stores the signal that forms the sub-pixel signal SPS output from the sub-pixel array 110, and senses and amplifies the signal before outputting the sub-pixel signal SPS. The readout block 190 may include a plurality of column memories (not shown), e.g., SRAMs, arranged in the columns of the sub-pixel array 110, respectively, to temporarily store the sub-pixel signal SPS; and a sense amplifier SA (not shown) to sense and amplify the temporarily stored sub-pixel signal SPS.

Returning to FIG. 1, the lens 500 may include a main lens 600 and a micro-lens array 700. The main lens 600 may be manufactured to have a size corresponding to the whole size of the sub-pixel array 110, and may cause an image of the object 400 to be focused. The micro-lens array 700 may include a plurality of micro-lenses 750. Each of the plurality of micro-lenses 750 may be manufactured to have a size corresponding to the size of a sub-pixel group of the sub-pixel array 110 (e.g., a first sub-pixel group 130-1 of FIG. 2) or the size of a pixel group (e.g., a first pixel group 150-1 of FIG. 3). Each of the plurality of micro-lenses 750 causes an image of the object 400 to be focused on a corresponding sub-pixel group (e.g., the first sub-pixel group 130-1 of FIG. 2) or a corresponding pixel group (e.g., the first pixel group 150-1 of FIG. 3).

FIG. 2 is a block diagram of an image sensor of FIG. 1 according to an exemplary embodiment.

Referring to FIGS. 1 and 2, an image sensor 100 includes a sub-pixel array 110a. The sub-pixel array 110a includes a plurality of sub-pixels 120 arranged in a matrix.

In an exemplary embodiment, each of the plurality of sub-pixels 120 may also be referred to as a jot. A sub-pixel pitch is less than a pixel pitch of a general image sensor. The plurality of sub-pixels 120 arranged in a matrix may be grouped into a plurality of sub-pixel groups. For example, the plurality of sub-pixels 120 may be grouped into a first sub-pixel group 130-1 to an n^{th} sub-pixel group.

Although FIG. 2 illustrates that each of the first sub-pixel group 130-1 to the n^{th} sub-pixel group includes four sub-pixels 120, exemplary embodiments are not limited thereto. The sub-pixel array 110a may output signals along column lines COL in units of rows, under control of the timing generator 170.

A color filter or a filter array (not shown) including a light-blocking film may be arrayed above each of the plurality of sub-pixels 120 constituting the sub-pixel array 110a to transmit or block light in a particular spectrum. Also, a pixel lens array (not shown) may be arrayed above each of the plurality of sub-pixels 120 constituting the sub-pixel array 110a to increase light gathering power of each of the plurality of sub-pixels 120.

Examples of a structure and operation of each of the plurality of sub-pixels 120 will be described in detail with reference to FIGS. 4A and 4B below.

The row driver block 160 drives a plurality of control signals CS1 and CS2 to the sub-pixel array 110a for controlling operations of the plurality of sub-pixels 120, respectively, under control of the timing generator 170. For example, the plurality of control signals CS1 and CS2 may be signals for selecting or resetting the plurality of sub-pixels 120, respectively.

Although not shown, the readout block 190 may include various elements (e.g., a memory or a sense amplifier circuit) for processing the signals output from the sub-pixel array 110a.

The sub-pixel signals SPS output from the readout block 190 may form different light-field images for the first sub-pixel group 130-1 to the n^{th} sub-pixel group. That is, the first sub-pixel group 130-1 to the n^{th} sub-pixel group may output the signals that pass through the corresponding micro-lenses 750 (see FIG. 1) and that correspond to a first sub-pixel image to an n^{th} sub-pixel image, respectively.

Returning to FIG. 1, the image signal processor 220 may generate angular information, depth data, and high-resolution images by processing the sub-pixel signals SPS corresponding to the first sub-pixel image to the n^{th} sub-pixel image, and refocus the high-resolution images.

FIG. 3 is a block diagram of an image sensor of FIG. 1 according to another exemplary embodiment.

Referring to FIGS. 1 to 3, an image sensor 100b includes a plurality of sub-pixels 120 arranged in a matrix. The plurality of sub-pixels 120 may be grouped into a plurality of sub-pixel groups. For example, the plurality of sub-pixels 120 may be grouped into a first sub-pixel group 140-1, a second sub-pixel group 140-2, a third sub-pixel group 140-3, to an n^{th} sub-pixel group.

Unlike the sub-pixel groups of FIG. 2, e.g., the first sub-pixel group 130-1, a red filter may be disposed on certain ones of the sub-pixel groups of FIG. 3, e.g., the first sub-pixel group 140-1, so that the entire first sub-pixel group 140-1 may act as one red (R) pixel. Alternatively, a blue filter or a green filter may be disposed on certain ones of the sub-pixel groups so that the entire sub-pixel group may act as one blue (B) pixel or one green (G) pixel respectively.

For example, the first sub-pixel group 140-1 may include a first sub-pixel SP11, a second sub-pixel SP12, a third sub-pixel SP13, and a fourth sub-pixel SP14.

Signals output from the respective first to fourth sub-pixels SP11 to SP14 will now be referred to as first to fourth sub-pixel signals SPS11 to SPS14, respectively.

The image signal processor 220 (see FIG. 1) may process the average of values of the first to fourth sub-pixel signals SPS11 to SPS14 as a pixel signal PS1 output from one R pixel.

The first sub-pixel group 140-1, the second sub-pixel group 140-2, to the n^{th} sub-pixel group may be grouped into the first pixel group 150-1 to an m^{th} pixel group (not shown) each including at least one among the first sub-pixel group 140-1 to the n^{th} sub-pixel group.

Sub-pixel signals SPS output from the first pixel group 150-1 to the m^{th} pixel group may form different light-field images for the first pixel group 150-1 to the m^{th} pixel group. That is, the first pixel group 150-1 to the m^{th} pixel group may output signals that pass through corresponding micro-lenses 750 and that correspond to a first pixel image to an m^{th} pixel image.

That is, the image signal processor 220 may form a plurality of pixels in units of these sub-pixel groups (e.g., the first sub-pixel group 140-1). For example, the image signal processor 220 may handle a result of combining the first to fourth sub-pixel signals SPS11 to SPS14 output from the respective sub-pixels SP11 to SP14 belonging to the first sub-pixel group 140-1, as a pixel signal PS1 output from one pixel. The image signal processor 220 may generate angular information, depth data, and high-resolution images by processing the sub-pixel signals SPS corresponding to the first sub-pixel image to the m^{th} sub-pixel image, and refocus the high-resolution images.

FIG. 4A is a circuit diagram of a sub-pixel of FIGS. 2 and 3 according to an exemplary embodiment.

Referring to FIGS. 2 to 4A, a sub-pixel 120-1 may be a binary pixel including a single transistor SX and a photodiode PD.

Although for convenience of explanation, FIG. 4A illustrates the sub-pixel 120-1 on an assumption that a photoelectric conversion device is a photodiode, exemplary embodiments are not limited thereto.

In an exemplary embodiment, the photoelectric conversion device may include at least one quantum dot (QD). For example, the photoelectric conversion device may include red quantum dots, green quantum dots, and blue quantum dots. Each of the red quantum dots, green quantum dots, and blue quantum dots may be excited by visible light to emit light.

A quantum dot is a nano-crystal formed of a semiconductor material, in which motions of all of electrons and holes that are two types of carriers in a semiconductor are limited three-dimensionally. Thus, an energy state density function of the quantum dot may be represented in the form of a delta function, and the quantum dot may have a discontinuous energy state, similar to that of hydrogen atoms.

The color of visible light emitted from a quantum dot may vary according to the size of particles thereof. For example, the smaller the size of the particles of the quantum dot, the shorter the wavelength of light emitted from the quantum dot, and the greater the size of the particles of the quantum dot, the longer the wavelength of light emitted from the quantum dot.

A quantum dot may have a size of about 1 nm to about 100 nm and a structure in which a central body is covered with a skin and the skin is coated with a polymer. In an exemplary embodiment, the central body may contain cadmium selenide (CdSe) and the skin may contain zinc sulfide (ZnS), but exemplary embodiments are not limited thereto. For example, the central body may contain cadmium telluride (CdTe) or cadmium sulfide (CdS).

In another exemplary embodiment, the photoelectric conversion device may include another device capable of converting light into an electric signal, rather than a photodiode and quantum dots.

One end of the photodiode PD may be connected to ground, and the other end thereof may be electrically connected to or disconnected from a body of the single transistor SX. A case in which the photodiode PD is electrically connected to the body of the single transistor SX will be described below.

The photodiode PD may generate light charges to be proportional to the intensity of incident light passing through the lens 500, and transmit the light charges to the body of the single transistor SX. The body of the single transistor SX includes a pocket capable of storing and retaining light charges. When the pocket is capable of storing and retaining (2ⁿ-1) light charges, the sub-pixel 120-1 is an n-bit binary pixel. Here, ‘n’ denotes a natural number.

In the single transistor SX, a source and a gate are connected to the row driver block 160 to receive a first control signal CS1 and a second control signal CS2, respectively. The sub-pixel 120-1 that is an exemplary embodiment of the sub-pixel 120 may have three operation modes (i.e., a light-charge accumulation mode, a reset mode, and a readout mode) according to the first control signal CS1 and the second control signal CS2.

The light-charge accumulation mode means a mode in which electrons or holes among light charges (electrons and holes) generated from incident light are accumulated or have been accumulated in the pocket.

The reset mode means a mode in which the light charges accumulated in the pocket are discharged via the source or drain of the single transistor SX.

The readout mode means a mode in which a sub-pixel signal SPSs corresponding to the light charges accumulated in the pocket is output via a column line COL. Examples of the sub-pixel signal SPS include a video signal and a reset signal. The video signal is output in the readout mode right after the light-charge accumulation mode ends, and the reset signal is output in the readout mode right after the reset mode ends.

Specifically, in the readout mode, a voltage of the body of the single transistor SX may vary according to the number of the light charges accumulated in the pocket, and a change in the voltage of the body of the single transistor SX results in a change in a threshold voltage Vth of the single transistor SX. When the threshold voltage Vth of the single transistor SX changes, an effect achieved when a voltage of the source of the single transistor SX changes may be produced. The sub-pixel 120-1 that is an exemplary embodiment of the sub-pixel 120 is capable of outputting a pixel signal in the form of a digital signal having at least two levels, based on this principle.

Here, a voltage generated when a first control signal CS1 is supplied to a source terminal of the single transistor SX will be defined as a source voltage Vs, a voltage generated when a second control signal CS2 is supplied to a gate terminal of the single transistor SX will be defined as a gate voltage Vg, a voltage output to a drain terminal of the single transistor SX will be defined as a drain voltage Vd, and a voltage applied to a semiconductor substrate in which the single transistor SX is formed will be defined as a substrate voltage Vsub.

In the light-charge accumulation mode, the source voltage Vs may be set to a first accumulation voltage VINT1, the gate voltage Vg may be set to a second accumulation voltage VINT2, and the substrate voltage Vsub may be set to 0 V so as to amplify light charges according to the avalanche effect. For example, when the single transistor SX is a PMOS transistor, the first accumulation voltage VINT1 may be 0 V and the second accumulation voltage VINT2 may be 0 V or a positive voltage ranging from about 0 V to about 5 V. Otherwise, when the single transistor SX is an NMOS transistor, the first accumulation voltage VINT1 may be 0 V and the second accumulation voltage VINT2 may be 0 V or a negative voltage ranging from about 0 V to about −5 V. As described above, when the light-charge accumulation mode is entered by applying a voltage to the single transistor SX, the single transistor SX may be deactivated, and light charges corresponding to the intensity of incident light are generated by the photodiode PD and accumulated in the pocket of the body of the single transistor SX. The drain voltage Vd may be 0 V.

In an exemplary embodiment, in order to amplify light charges according to the avalanche effect, a high voltage (e.g., about 3.3 V or more when the single transistor SX is a PMOS transistor) or a low voltage (e.g., about −3.3 V or less when the single transistor SX is an NMOS transistor) may be applied to the source S or the drain D of the single transistor SX rather than the gate G thereof.

In another exemplary embodiment, in order to prevent light charges from being accumulated in the pocket, a specific voltage (a negative voltage when the single transistor SX is a PMOS transistor or a positive voltage when the single transistor SX is an NMOS transistor) may be applied to the source S and the drain D of the single transistor SX. That is, an electric shutter function may be performed by adjusting voltages of the source S and the drain D.

In the reset mode, the source voltage Vs may be set to a first reset voltage VRESET1, the gate voltage Vg may be set to a second reset voltage VRESET2, and the substrate voltage Vsub may be set to 0 V. For example, when the single transistor SX is a PMOS transistor, the first reset voltage VRESET1 may be a positive voltage that is equal to or greater than 1.5 V and the second reset voltage VRESET2 may be 0 V. When the single transistor SX is an NMOS transistor, the first reset voltage VRESET1 may be a negative voltage that is less than or equal to −1.5 V and the second reset voltage VRESET2 may be 0 V. As described above, when the reset mode is entered by applying a voltage to the single transistor SX, light charges accumulated in the pocket may be reset by a semiconductor substrate in which the single transistor SX is formed. The drain voltage Vd may be 0 V.

In the readout mode, the source voltage Vs may be set to a first read voltage VREAD1, the gate voltage Vg may be set to a second read voltage VREAD2, and the substrate voltage Vsub may be set to 0 V. For example, when the single transistor SX is a PMOS transistor, the first read voltage VREAD1 may be equal to a power supply voltage VDD, and the second read voltage VREAD2 may be lower than the threshold voltage Vth of the single transistor SX when the single transistor SX is not influenced by the photodiode PD. When the single transistor SX is an NMOS transistor, the first read voltage VREAD1 may be equal to the power supply voltage VDD, and the second read voltage VREAD2 may be higher than the threshold voltage Vth of the single transistor SX when the single transistor SX is not influenced by the photodiode PD. The power supply voltage VDD may correspond to a power supply voltage of the image sensor 100 and may be in the range of about −3 V to about 3 V.

As described above, when the readout mode is entered by applying a voltage to the single transistor SX, the drain voltage Vd may be output as the sub-pixel signal SPS by sensing a change in the threshold voltage Vth of the single transistor SX according to the amount of the light charges accumulated in the pocket.

For example, it is assumed that the threshold voltage Vth of the single transistor SX is 1 V when the single transistor SX is an NMOS transistor and is not influenced by the photodiode PD. Also, it is assumed that that the threshold voltage Vth of the single transistor SX changes to 1.4 V when one light charge is generated by the photodiode PD. When one light charge is generated by the photodiode PD, the single transistor SX may be activated (i.e., turned on) to output a sub-pixel signal SPS having a high level, e.g., 1 V. When no light charge is generated by the photodiode PD, the single transistor SX may be deactivated (i.e., turned off) to output a sub-pixel signal SPS having a low level, e.g., 0 V.

FIG. 4B is a circuit diagram of a sub-pixel of FIGS. 2 and 3 according to another exemplary embodiment.

Referring to FIGS. 2 to 4B, a sub-pixel 120-2 may be an analog pixel including a photodiode PD and a read circuit 121.

Although for convenience of explanation, it is assumed in FIG. 4B that a photoelectric conversion device is the photodiode PD, exemplary embodiments are not limited thereto. For example, the photoelectric conversion device may be quantum dots (QD).

The read circuit 121 may include a floating diffusion node FD, a reset transistor RT, a source follower transistor SF, and a selection transistor ST.

Light charges generated by the photodiode PD may be accumulated in the floating diffusion node FD.

The reset transistor RT may discharge the light charges accumulated in the floating diffusion node FD according to a reset signal RG.

The source follower transistor SF may amplify the light charges accumulated in the floating diffusion node FD and convert the light charges into a video signal.

The selection transistor ST may selectively output the video signal according to a selection signal SEL.

Although FIG. 4B illustrates the sub-pixel 120-2 as having a three-transistor (3T) structure, this is only an example, and other exemplary embodiments may have a sub-pixel having a four-transistor (4T) structure. For example, the read circuit 121 may further include a transfer transistor (not shown) that is connected between the photodiode PD and the floating diffusion node FD and transfers light charges to the floating diffusion node FD according to a transmission signal.

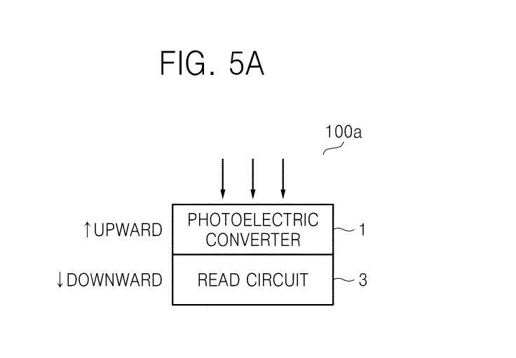

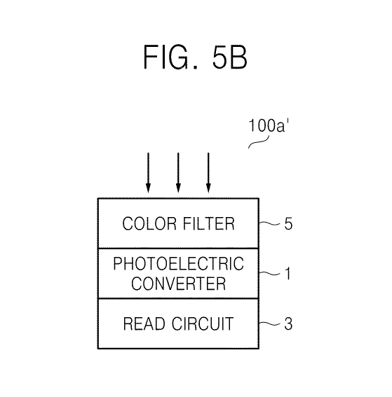

FIG. 5A is a diagram illustrating an image sensor according to an exemplary embodiment.

Referring to FIG. 5A, an image sensor 100a may include a photoelectric converter 1 and a read circuit 3.

The photoelectric converter 1 may be formed on a first layer, and generate light charges by receiving light. The photoelectric converter 1 may include at least one photodiode PD such as that illustrated in FIG. 4A or 4B.

In another exemplary embodiment, the photodiode PD of FIG. 4A or 4B may be replaced with quantum dots. Thus, the photoelectric converter 1 may include at least one quantum dot.

The read circuit 3 may be formed on a second layer below the first layer, and accumulate the light charges and produce a video signal according to the amount of the accumulated light charges.

Each of pixels of the image sensor 100a may be a binary pixel or an analog pixel.

In the present disclosure, a remaining portion of a pixel excluding a photoelectric converter has been defined as a read circuit. The read circuit 3 may include a read circuit of each of the pixels.

For example, when each of the pixels is a binary pixel, the read circuit 3 may include the single transistor SX of FIG. 4A for each of the pixels. When each of the pixels is a three transistor pixel, the read circuit 3 may include the read circuit 121 of FIG. 4B for each of the pixels.

In another exemplary embodiment, the read circuit 3 may further include the elements of the image sensor 100 of FIG. 1 except for the sub-pixel array 110, e.g., the row driver block 160, the timing generator 170, the control register block 180, and the readout block 190. In other words, the read circuit 3 may further include the elements of the row driver block 160, the timing generator 170, the control register block 180, and the readout block 190.

FIG. 5B is a diagram illustrating an image sensor according to another exemplary embodiment. An image sensor 100a′ of FIG. 5B has substantially the same structure as the image sensor 100a of FIG. 5A and will be thus described focusing the differences from the image sensor 100a of FIG. 5A below for convenience of explanation.

Referring to FIG. 5B, the image sensor 100a′ may further include a color filter 5 formed on the first layer to be in contact with the first layer, compared to the image sensor 100a. In another exemplary embodiment, an infrared (IR) pass filter may be formed on the first layer instead of the color filter.

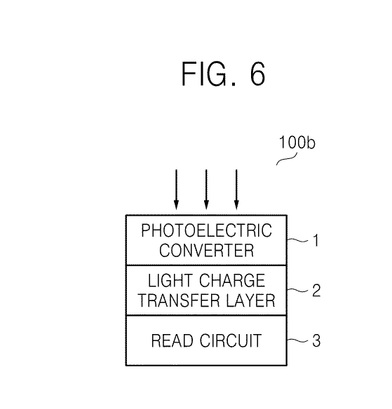

FIG. 6 is a diagram illustrating an image sensor according to another exemplary embodiment.

Referring to FIG. 6, an image sensor 100b may include a photoelectric converter 1, a light charge transfer layer 2, and a read circuit 3.

The photoelectric converter 1 may be formed on a first layer, and generate light charges by receiving light. The photoelectric converter 1 may include at least one quantum dot or at least one photodiode.

The read circuit 3 may be formed on a second layer below the first layer, and accumulate the light charges and produce a video signal according to the amount of the accumulated light charges.

The light charge transfer layer 2 may be formed on a third layer between the first and second layers, and transfer the light charges to the read circuit 3.

Each of pixels of the image sensor 100b may be a binary pixel or an analog pixel. The read circuit 3 may include a read circuit of each of the pixels.

For example, when each of the pixels is a binary pixel, the read circuit 3 may include the single transistor SX of FIG. 4A for each of the pixels. When each of the pixels is a 3T pixel, the read circuit 3 may include the read circuit 121 of FIG. 4B for each of the pixels.

In another exemplary embodiment, the read circuit 3 may further include the elements of the image sensor 100 of FIG. 1 except for the sub-pixel array 110, e.g., the row driver block 160, the timing generator 170, the control register block 180, and the readout block 190.

In another exemplary embodiment, the image sensor 100b may further include the color filter 5 or an IR pass filter (not shown) formed on the first layer to be in contact with the first layer.

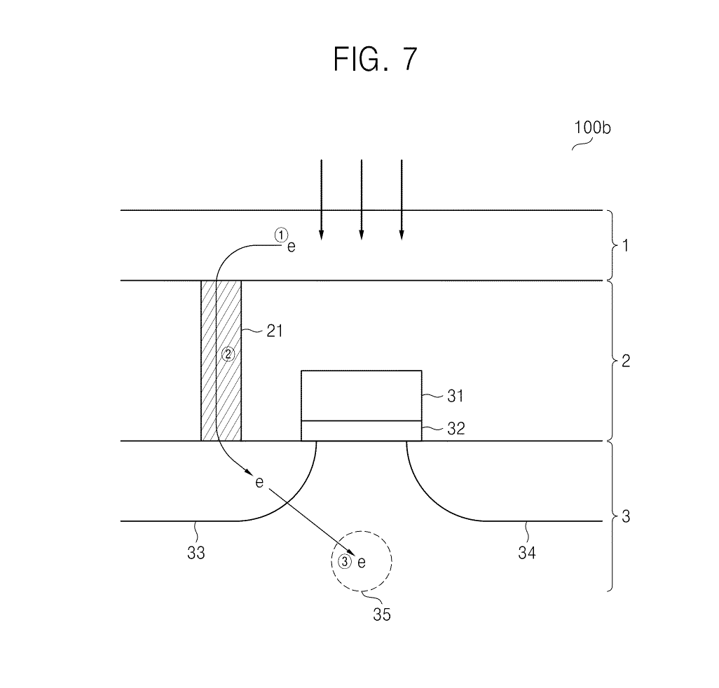

FIG. 7 is a diagram illustrating an operation of the image sensor of FIG. 6 according to an exemplary embodiment.

Referring to FIGS. 4A, 6, and 7, the read circuit 3 may include the single transistor SX of FIG. 4A for each of the pixels. The single transistor SX of FIG. 4A may include a gate 31, an insulating layer 32, a drain 33, a source 34, and a pocket 35.

The pocket 35 is capable of accumulating at least one light charge (e). The at least one light charge (e) may be a hole or an electron. The pocket 35 may be located in the body of the single transistor TX, but exemplary embodiments are not limited thereto.

An operation of the image sensor 100b will now be described. The photoelectric converter 1 generates the at least one light charge (e) by receiving light from the outside (operation \textcircled{1}). The at least one light charge (e) is transferred to the single transistor SX via a through-electrode 21 (operation \textcircled{2}).

Although FIG. 7 illustrates that the through-electrode 21 is connected to the drain 33, exemplary embodiments are not limited thereto. For example, in other exemplary embodiments, the through-electrode 21 may be connected to the source 34, the drain 33, or a region adjacent to the source 34 or the drain 33.

The transferred at least one light charge (e) may be accumulated in the pocket 35 when high voltage is applied to the gate 31 (operation \textcircled{3}). The accumulated at least one light charge (e) may change a threshold voltage Vth of the single transistor SX.

Each of photoelectric conversion elements (e.g., photodiodes or quantum dots) of the photoelectric converter 1 and each of the single transistors SX of the read circuit 3 may correspond to each other and be electrically connected via the through-electrode 21. However, exemplary embodiments are not limited thereto and this structure may be modified by those of ordinary skill in the art.

For example, light charges generated by one photodiode may be distributed to a plurality of single transistors SX via one through-electrode.

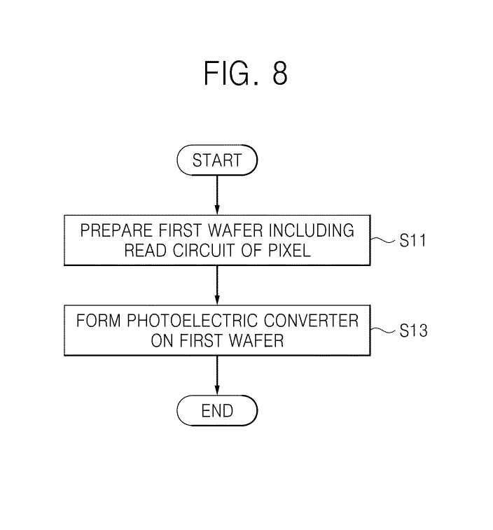

FIG. 8 is a flowchart of a method of manufacturing an image sensor according to an exemplary embodiment.

Referring to FIG. 8, a first wafer including a read circuit of a pixel is prepared (operation S11).

A photoelectric converter is formed on the first wafer (operation S13).

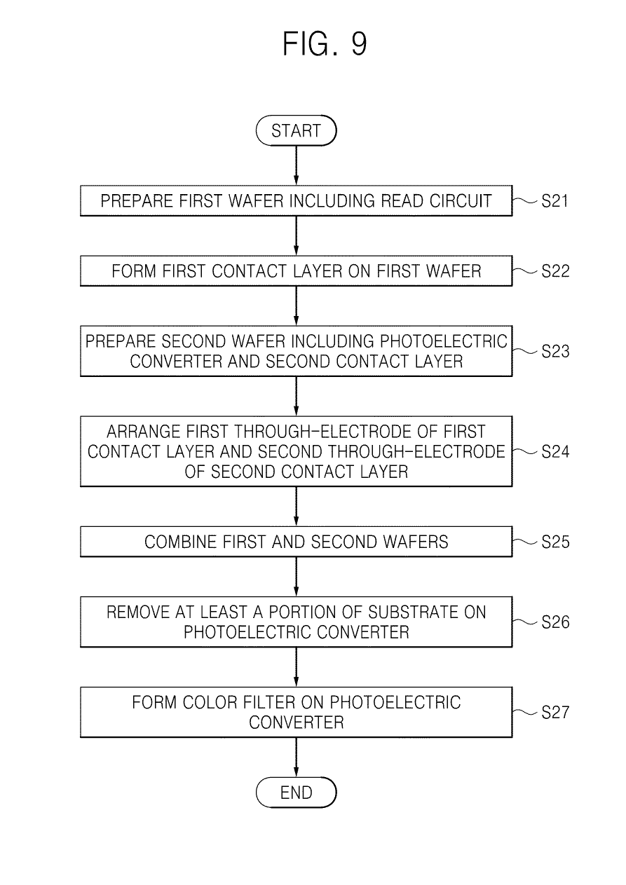

In another exemplary embodiment, a process of combining the first wafer with a second wafer may be performed to form the photoelectric converter. This process will be described in detail with reference to FIGS. 9 to 14 below for convenience of explanation.

In another exemplary embodiment, the photoelectric converter may be formed on the first wafer without combining the two wafers.

For example, the photoelectric converter may be formed by forming a light charge transfer layer on the first wafer, and depositing amorphous silicon on the light charge transfer layer.

The photoelectric converter may be formed by doping amorphous silicon. For example, a photodiode may be formed by doping n-type or p-type impurities into the amorphous silicon or quantum dots may be formed by doping a nano-crystal into the amorphous silicon.

The pixel may be a binary pixel including a single transistor capable of accumulating light charges in a body thereof.

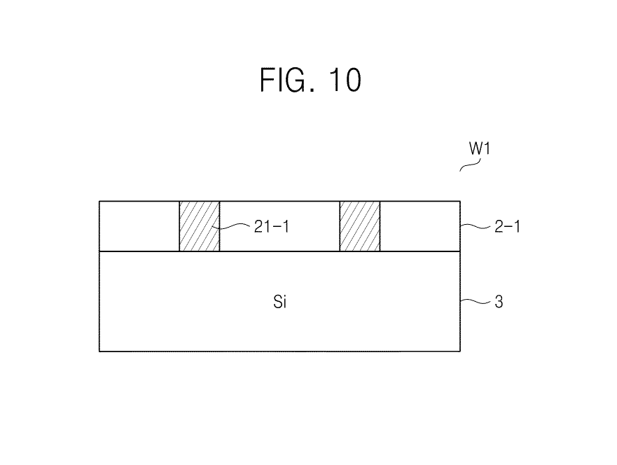

FIG. 9 is a flowchart of a method of manufacturing the image sensor of FIG. 6 according to an exemplary embodiment. FIGS. 10 to 14 are cross-sectional views sequentially illustrating a method of manufacturing the image sensor of FIG. 6 according to an exemplary embodiment.

Referring to FIGS. 9 and 10, a first wafer W1 including a read circuit 3 is prepared (operation S21). Then, a first contact layer 2-1 including at least one first through-electrode 21-1 is formed on the first wafer W1 (operation S22).

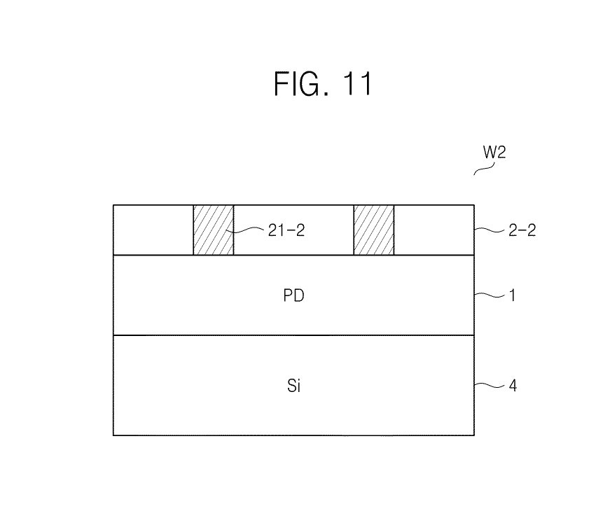

Referring to FIGS. 9 and 11, a second wafer W2 including a photoelectric converter 1 and a second contact layer 2-2 is prepared (operation S23). The second contact layer 2-2 includes at least one second through-electrode 21-2. The second wafer W2 may further include a substrate 4 below the photoelectric converter 1.

In another exemplary embodiment, the first through-electrode 21-1 and the second through-electrode 21-2 may be each formed of copper (Cu) or aluminum (Al).

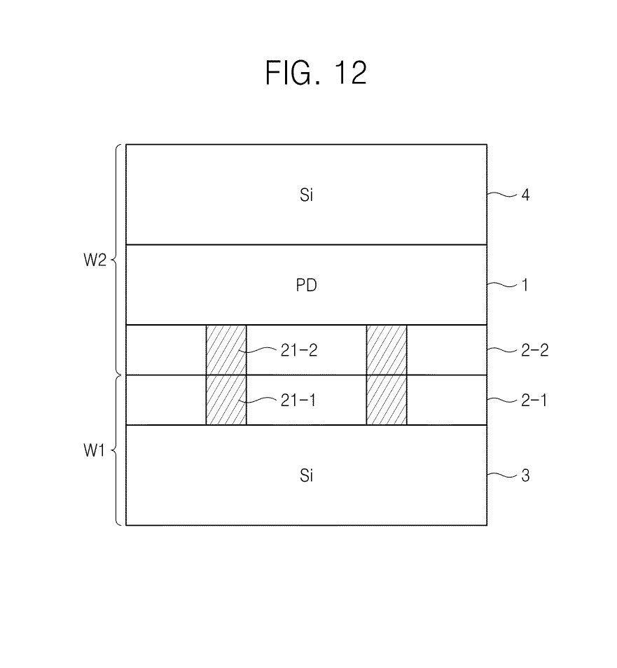

Referring to FIGS. 9 and 12, a first through-electrode 21-1 of a first contact layer 2-1 and a second through-electrode 21-2 of a second contact layer 2-2 are arranged (operation S24). That is, the first through-electrode 21-1 and the second through-electrode 21-2 are arranged to coincide with each other. Then, the first wafer W1 and the second wafer W2 are combined to connect the first through-electrode 21-1 and the second through-electrode 21-2 to each other (operation S25).

Referring to FIGS. 9, 12, and 13, a light charge transfer layer 2 is a combination of the first contact layer 2-1 and the second contact layer 2-2, and a through-electrode 21 is a combination of the first through-electrode 21-1 and the second through-electrode 21-2.

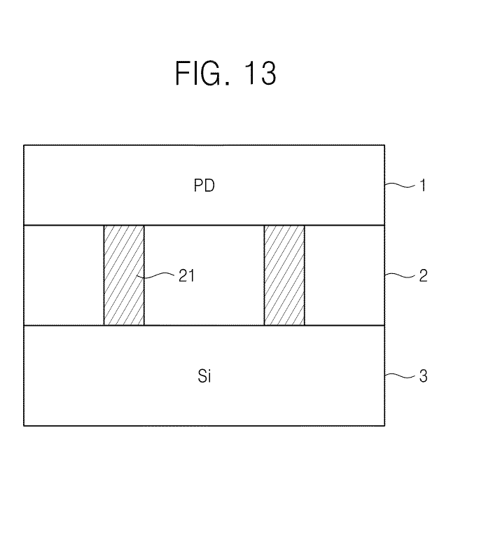

After the first wafer W1 and the second wafer W2 are combined with each other, at least a portion of the substrate 4 placed on the photoelectric converter 1 of the second wafer W2 may be removed (operation S26). In another exemplary embodiment, a process of removing the substrate 4 may be performed using a thinning process or a back-grinding process. FIG. 13 illustrates an image sensor obtained after the substrate 4 is removed.

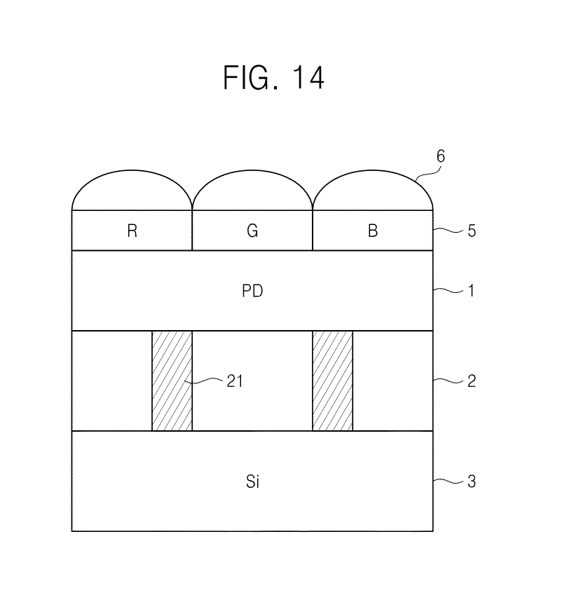

Referring to FIGS. 9 and 14, after at least a portion of the substrate 4 is removed, a color filter 5 may be formed on the photoelectric converter 1 (operation S27). In another exemplary embodiment, another filter, e.g., an IR pass filter, may be formed instead of the color filter 5.

In another exemplary embodiment, a micro-lens 6 may be further formed on the color filter 5. In yet another exemplary embodiment, a padding process may be further performed thereafter.

A photoelectric converter and a read circuit of an image sensor according to the related art are formed on the same layer and thus increasing an area of the photoelectric converter is limited. Also, since, in a binary sensor according to the related art, a photoelectric converter is formed below a single transistor, the binary sensor is difficult to receive light and thus has low sensitivity.

By contrast, in an image sensor according to an exemplary embodiment, a photoelectric converter is formed on a different layer from a layer on which a read circuit is formed and may be thus formed in a larger area than in an image sensor according to the related art. Thus, a larger area of the image sensor is capable of receiving light and thus has an improved resolution. Also, since the photoelectric converter is disposed below a color filter, a light reaction is more likely to occur, thereby increasing sensitivity.

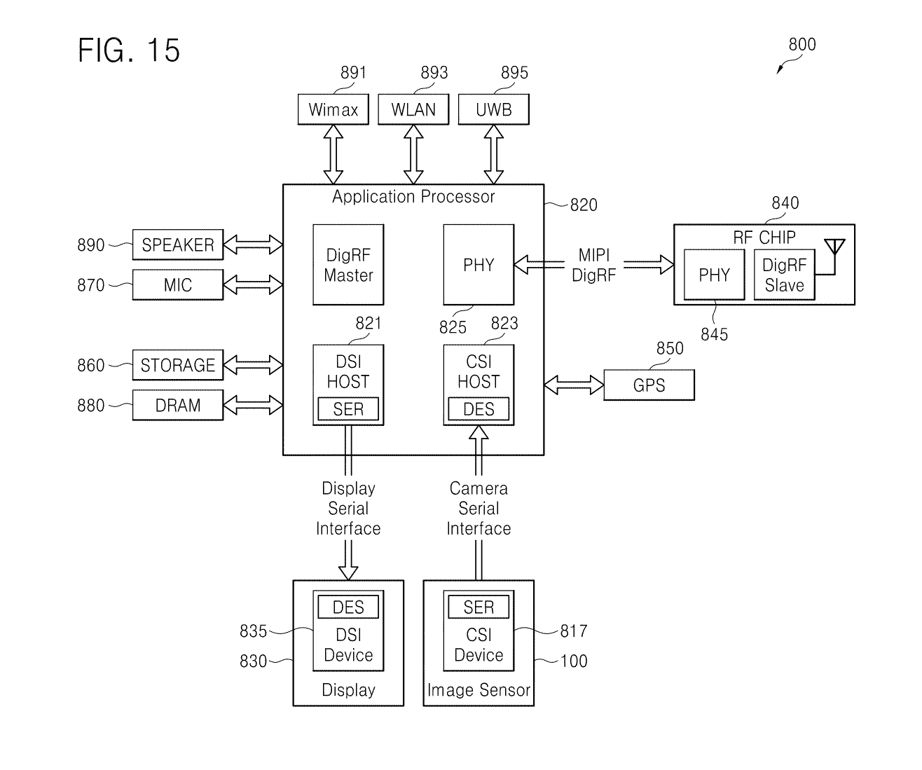

FIG. 15 is a block diagram of an image sensing system including an image sensor illustrated in FIG. 1 according to some exemplary embodiments. An image sensing system 800 may be implemented by a data processing apparatus, such as a mobile phone, a personal digital assistant (PDA), a portable media player (PMP), an internet protocol television (IPTV), a tablet PC, or a smart phone that can use or support a mobile industry processor interface (MIPI). The image sensing system 800 includes the image sensor 100, an application processor 820, and a display 830. The image sensor 100 and an image signal processor (not shown) for processing image data output from the image sensor 100 may be implemented as a single chip.

A camera serial interface (CSI) host 823 included in the application processor 820 performs serial communication with a CSI device 817 included in an image sensor 100 through CSI. For example, a de-serializer (DES) may be implemented in the CSI host 823, and a serializer (SER) may be implemented in the CSI device 817.

A display serial interface (DSI) host 821 included in the application processor 820 performs serial communication with a DSI device 835 included in the display 830 through DSI. For example, a serializer (SER) may be implemented in the DSI host 821, and a de-serializer (DES) may be implemented in the DSI device 835.

According to some exemplary embodiments, the image sensing system 800 may also include a radio frequency (RF) chip 840 which communicates with the application processor 820. A physical layer (PHY) 825 of the application processor 820 and a PHY 845 of the RF chip 840 communicate data with each other according to a MIPI DigRF standard. The image sensing system 800 may further include a GPS 850, a storage device 860, a microphone 870, a DRAM 880 and a speaker 890.

The image sensing system 800 may communicate using World Interoperability for Microwave Access (Wimax) 891, Wireless LAN (WLAN) 893 and/or Ultra Wideband (UWB) 895, etc.

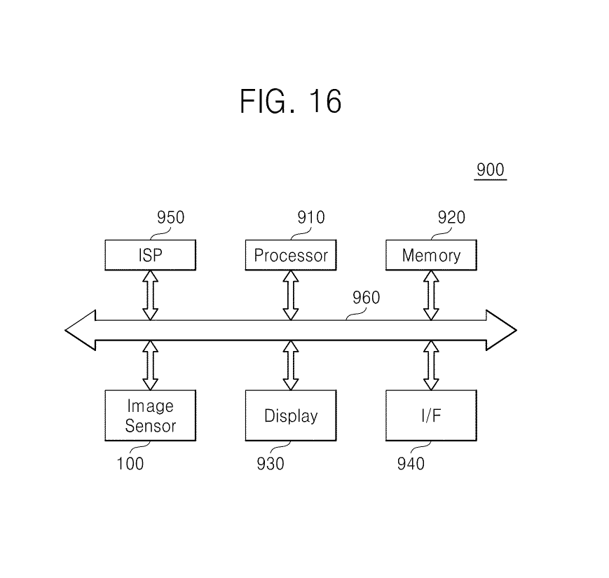

FIG. 16 is a block diagram of an image sensing system including an image sensor illustrated in FIG. 1 according to other exemplary embodiments. Referring to FIGS. 1 and 16, an image sensing system 900 includes the image sensor 100, a processor 910, a memory 920, a display 930, an interface 940, and an image signal processor 950.

The processor 910 may control the operation of the image sensor 100. The image signal processor 950 may perform various operations (for example, image scaling and image enhancement) on signals output from the image sensor 100. According to some exemplary embodiments, the image sensor 100 and the image signal processor 950 may be implemented as a single chip. The image signal processor 950 may be the image signal processor 220 illustrated in FIG. 1.

The memory 920 may store commands for controlling operation of the image sensor 100 and the image data generated by the processor 910 or the image signal processor 950 via a bus 960. The processor 910 may execute the commands stored in the memory 920. For example, the memory 920 may be implemented by a non-volatile memory like flash memory.

The display 930 may receive the image data output from the processor 910 or the memory 920 and display the received image data. For example, the display 930 may be a liquid crystal display (LCD), a light emitting diode (LED) display, an organic LED (OLED) display, an active matrix organic light emitting diodes (AMOLED) display or a flexible display.

The interface 940 may be implemented as an interface for inputting and outputting the image data. For example, the interface 940 may be implemented by a wireless interface.

According to the one or more exemplary embodiments, in an image sensor, a photoelectric converter may be formed on a different layer from a layer on which a read circuit is formed and be thus formed in a large area. Thus, since a large area of the image sensor receives light, the resolution of the image sensor increases. Also, the photoelectric converter is disposed below a color filter and the sensitivity of the image sensor increases.

While certain exemplary embodiments have been particularly shown and described, it will be understood that various changes in form and details may be made therein without departing from the spirit and scope of the following claims.

1. An image sensor comprising:
a photoelectric converter formed on a first layer and configured to generate light charges by receiving light;
a read circuit formed on a second layer below the first layer, and configured to accumulate the generated light charges and produce a video signal according to an amount of the accumulated light charges; and
a light charge transfer layer formed on a third layer between the first layer and the second layer, and configured to transfer the generated light charges to the read circuit,
wherein the read circuit comprises a single transistor, and
the light charges are accumulated in a body of the single transistor.

2. The image sensor of claim 1, wherein a threshold voltage of the single transistor varies according to the amount of the light charges accumulated in the body.

3. The image sensor of claim 1, wherein the light charges are transferred from the photoelectric converter to a source or a drain of the single transistor or to a region adjacent to the source or the drain, and then accumulated in the body of the single transistor.

4. The image sensor of claim 1, wherein the photoelectric converter comprises at least one quantum dot.

5. The image sensor of claim 4, wherein the at least one quantum dot comprises red quantum dots, green quantum dots, and blue quantum dots.

6. The image sensor of claim 4, wherein the at least one quantum dot is excited by visible light to emit light.

7. The image sensor of claim 4, wherein the at least one quantum dot comprises:
a central body containing cadmium selenide (CdSe); and
a skin containing zinc sulfide (ZnS).

8. The image sensor of claim 4, wherein the at least one quantum dot comprises a plurality of quantum dots, and each quantum dot emits visible light having a different color that the other quantum dots according to a size of particles thereof.

9. The image sensor of claim 4, wherein the at least one quantum dot has a size of about 1 nm to about 100 nm.

10. The image sensor of claim 1, wherein the photoelectric converter comprises at least one photodiode.

11. The image sensor of claim 1, further comprising a color filter or an infrared pass filter formed on the first layer to be in contact with the first layer.

12. The image sensor of claim 1, comprising:
a first silicon substrate including the first layer; and
a second silicon substrate including the second layer, the second silicon substrate being combined with a bottom of the first silicon substrate.

13-24. (canceled)

25. An image processing system comprising:
an image sensor; and
an image processor configured to process an output signal of the image sensor,
wherein the image sensor comprises:
a quantum dot layer configured to generate light charges by receiving light;
a light charge transfer layer formed below the quantum dot layer and configured to transfer the light charges downward; and
a read circuit layer formed below the light charge transfer layer, including at least one binary pixel, each of the at least one binary pixel including a single transistor, and configured to accumulate the light charges in a body of the single transistor and generate the output signal according to an amount of the light charges accumulated in the body.

26. An image sensor comprising:
a plurality of sub-pixels, each sub-pixel comprising a photodiode and a transistor;
wherein the photodiodes of the plurality of sub-pixels are formed in a first layer as a photoelectric converter of the image sensor, and
wherein the transistors of the plurality of sub-pixels are formed in a second layer of the image sensor as a read circuit, the second layer being below the first layer, the transistors accumulating light charges from the sub-pixels generated by the respective photodiodes, and the read circuit producing an image signal according to an amount of the accumulated light charges.

27. The image sensor of claim 26, wherein each transistor comprises a body, and wherein the light charges are accumulated in the bodies of the transistors.

28. The image sensor of claim 26, further comprising:
for each of the plurality of sub-pixels, a through-electrode connecting the photodiode of the sub-pixel to a source or drain of the transistor of the sub-pixel,
wherein the through-electrodes are formed in a third layer of the image sensor as a light charge transfer layer, the third layer being between the first layer and the second layer, and
wherein, for each of the plurality of sub-pixels the light charges are accumulated on the body of the transistor of the sub-pixel.

29. The image sensor of claim 26, wherein each sub-pixel comprises the photodiode and a plurality of transistors, and the transistors of the plurality of sub-pixels are formed in the second layer of the image sensor as the read circuit.
